(19) United States
(12) Patent Application Publication
(10) Pub. No.: US 2025/0015008 A1
(43) Pub. Date: Jan. 9, 2025

(54) DIE EMBEDDED PACKAGE AND METHOD OF FORMING A DIE EMBEDDED PACKAGE

(71) Applicant: Infineon Technologies AG, Neubiberg (DE)

(72) Inventors: Mahadi-Ul HASSAN, Bayern (DE); Angela KESSLER, Sinzing (DE); Martin Andrew NAVARRE, Villach (AT); Tobias POLSTER, Finkenstein (AT)

(73) Assignee: Infineon Technologies AG, Neubiberg (DE)

(21) Appl. No.: 18/764,578

(22) Filed: Jul. 5, 2024

(30) Foreign Application Priority Data
Jul. 6, 2023 (DE) 10 2023 206 437.5

(51) Int. Cl. H01L 23/538; H01L 21/48; H01L 21/56; H01L 23/00; H01L 23/31; H01L 23/498; H01L 23/544; H01L 25/065

(52) U.S. Cl. CPC H01L 23/5389; H01L 21/486; H01L 21/56; H01L 23/3135; H01L 23/49827; H01L 23/544; H01L 24/08; H01L 25/0655; H01L 2223/54426; H01L 2224/08235; H01L 2924/1815

(57) ABSTRACT

A die embedded package is disclosed. In one example, the die embedded package includes a first bare die and a second bare die, the first bare die being thinner than the second bare die, a first encapsulation material encapsulating the first bare die, wherein the total thickness of the first encapsulation and the first bare die is approximately equal to the thickness of the second bare die. An outer surface of the first encapsulation material and an outer surface of the second bare die are arranged coplanarly. A first and second set of electrically conductive vias electrically contact the first bare die. A third set of electrically conductive vias electrically contacts the second bare die.

### CROSS-REFERENCE TO RELATED APPLICATION

This Utility Patent application claims priority to German Patent Application No. 10 2023 206 437.5 filed Jul. 6, 2023, which is incorporated herein by reference.

### TECHNICAL FIELD

Various embodiments relate generally to a die embedded package and to a method of forming a die embedded package.

### BACKGROUND

Due to requirements for thinner and thinner dies (for example from presently used dies with a thickness of 60 μm to dies having a thickness of 40 μm), a handling of the bare dies has turned out to be more and more critical. Especially when the dies are embedded inside a PCB laminate with a die embedding technology, the embedding may be done by the PCB manufacturer, who may possibly have only limited experience regarding handling thin dies, the risk of damages (e.g. cracking, chipping, etc.) during die handling and embedding may be high.

Another critical topic for die embedding packaging (also referred to as chip embedding (CE) packaging) that ultra-thin dies, e.g., SFET dies, may cause is the following: Although the thinning process may already be available for MOSFET dies (such as the SFET dies), the process to thin down the driver dies to the same thicknesses (e.g., 40 μm) may not be available yet. The different die thickness may lead to a situation in which microvias on the die front and back side of the ultra thin die (e.g., the SFET) may have different depth. This may make design rules, laser drilling and plating processes (e.g., a filling of vias) more complicated. Moreover, an increase in via depth may eventually decrease an effective contact area on the die pad because of the near cone shape via. This may mean that non-equal contact areas are formed on both sides of the die.

The problem is visualized in FIG. 3, which shows a die embedded package where the die 102 is so thin (e.g., compared to the core 104 and/or to a second die (not shown, but the same problem as described in context with FIG. 3 also applies to FIG. 1, even though the vias of this (multi-) die embedded package 100 according to a prior art are simplified as straight lines instead of cone shapes)) that a contact area (indicated by arrows) on the side of the die 102 where a microvia 102V is required to be longer is significantly smaller than on the other side of the die 102, which has the shorter microvia 102V. A difference in diameter of the contact area is indicated by the second arrow on the bottom side.

Until today, the problem that ultra-thin dies are causing is yet unsolved. There exists no proven concept that allows to embed the ultra-thin dies (e.g., with a thickness of about 40 μm) inside a carrier, e.g., a PCB laminate, in a reliable way and with good yield.

There exists a possibility that the driver die cannot be thinned down to the same thickness as the SFETs. However, it may be required to embed dies with different thicknesses (e.g., 40 μm and 60-100 μm) inside the one package. This may not be possible in a cost effective way using the present die embedding process.

### SUMMARY

A die embedded package is provided. The die embedded package may include a first bare die and a second bare die, the first bare die being thinner than the second bare die, a first encapsulation material encapsulating the first bare die, wherein the total thickness of the first encapsulation and the first bare die is approximately equal to the thickness of the second bare die and wherein an outer surface of the first encapsulation material and an outer surface of the second bare die are arranged coplanarly, a second encapsulation material encapsulating the encapsulated first bare die and the second bare die. a first set of electrically conductive vias electrically contacting the first bare die from a first side of the first bare die and a second set of electrically conductive vias electrically contacting the first bare die from a second side of the first bare die, the second side opposite to the first side, and a third set of electrically conductive vias electrically contacting the second bare die from a first side of the second bare die or from a second side of the second bare die.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic cross-sectional view of a die embedded package in accordance with a prior art;

FIG. 2 shows a schematic cross-sectional view of a die embedded package in accordance with various embodiments;

FIG. 3 shows a schematic cross-sectional view of a die embedded package in accordance with a prior art;

FIG. 4 shows a schematic cross-sectional view of a die embedded package in accordance with various embodiments;

FIG. 5 shows a schematic cross-sectional view of a die embedded package in accordance with a prior art;

each of FIGS. 6A to 6C shows a schematic cross-sectional view of a die embedded package in accordance with various embodiments;

FIG. 7A shows a schematic cross-sectional view of a die embedded package in accordance with a prior art;

FIG. 7B shows a schematic cross-sectional view of a die embedded package in accordance with various embodiments;

FIG. 8A shows a schematic top view and a schematic cross-sectional view of a die with encapsulation material as used in a die embedded package in accordance with a prior art;

each of FIGS. 8B to 8E shows a schematic top view and a schematic cross-sectional view of a die with encapsulation material as used in a die embedded package in accordance with various embodiments;

FIG. 9 illustrates, as a sequence of individual panels, a method of forming a die embedded package in accordance with various embodiments;

each of FIGS. 10A, 10B, and 11 shows a schematic cross-sectional view of a die with encapsulation material as used in a die embedded package in accordance with various embodiments;

FIG. 12 shows a schematic top view of a die with encapsulation material as used in a die embedded package in accordance with various embodiments; and

FIG. 13 shows a flow diagram of a method of forming a die embedded package in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

The terms “chip” and “die” are used as synonyms herein.

“Microvias” are also referred to as “vias” herein.

In various embodiments, a die embedded package and a method for forming it are provided that allows thin dies and/or dies with different thicknesses to be embedded inside a (e.g. common) PCB laminate in a reliable way and without any major changes to existing manufacturing processes. Various embodiments may in particular be relevant in a context of double sided chip embedding (CE2).

The dies may in various embodiments be protected by additional protection layer(s) (for example, encapsulation layer(s), e.g. prepreg or a molding material) to increase the thickness of the dies and to make the die more robust for handling. The dies may be protected from one or both main sides with additional molded, laminated or coated layer(s).

The protection layer may in various embodiments fully cover one or both of the main surfaces (and optionally the side surfaces), or the protection layers may be structured in regions where this may be appropriate, i.e. via landing areas.

In various embodiments, dies with a protection layer on one or both of their main surfaces are provided. This protection layer(s) may increase a thickness of the die and thus make the dies more robust against the handling during the die placement and embedding processes. The protection layer(s) may furthermore make an embedding of thin dies together with thicker dies inside the same package easier.

Increasing the thickness of the thin die with protective layer(s) makes it possible to shift (e.g., vertically, orthogonal to a horizontal plane that is parallel to main surfaces of the die) an active surface of the embedded thin die towards a middle (e.g., a central plane) of a core layer. The core layer may be part of a die embedded package that includes the thin die, and the thin die may be arranged in an opening of the core layer.

For the (vertically) shifted thin die, a depth of microvias that may be arranged for electrically contacting the thin die from two opposite main sides of the die may be symmetrical on both sides. In other words, the microvias on both sides of the die may be of approximately equal length, at least for some of the microvias.

In various embodiments, the protective layer(s), e.g. the encapsulation layer(s), may be provided as structured top- and/or bottom layers to enhance a handling capability, und to furthermore facilitate processing, especially during die handling and laser via drilling. The protective layer(s), e.g. the encapsulation material, may be configured to enhance the adhesion on one more, e.g. both main sides, of the die (e.g., on the die side facing towards metal pads and on the other side towards the embedding materials. Thereby, a risk of delamination may be reduced.

FIG. 2 shows a schematic cross-sectional view of a die embedded package 200 in accordance with various embodiments. The die embedded package 200 may have a first side 200S1 (in the Figures the bottom side) and a second side 200S2 (in the Figures the top side). For other elements included in the die embedded package 200, their respective sides arranged in the same direction as the first side 200S1 of the die embedded package 200 are also referred to as first side S1, and mutatis mutandis for the second side (200) S2. The first bare die 102 may be a double-sided die having die contacts 102M on its first side (referred to as die contacts 102_1MS1) and on its second side (referred to as die contacts 102_1MS2).

The die embedded package 200 may include a first bare die 102 and a second bare die 106 (optionally next to each other), the first bare die 102 being thinner than the second bare die 106.

The first bare die 102 may for example be or include a semiconductor device like a field effect transistor, for example a MOSFET. For such types of die, thinning technologies may already exist that allow thinning to a die thickness of below 60 μm, below 50 μm, or below 40 μm, for example to a thickness of between 30 μm and 50 μm, for example around 40 μm. In other embodiments, the first bare die 102 may be any other type of die with a thickness in the range specified above.

The second bare die 106 may for example be a control die, also referred to as a driver die. As described above, thinning techniques that allow a thinning of control dies may not exist at present. Control dies may typically have a thickness in a range from about 60 μm to about 100 μm. Optionally, the second bare die 106 may be a single-sided die having die contacts only on its first side or only on its second side. In other embodiments, the second bare die 106 may have die contacts on both opposite main sides.

Hence, the first bare die 102 may be thinner than the second bare die 106.

The die embedded package 200 may further include a first encapsulation material 220 (also referred to as first encapsulation 220) encapsulating the first bare die 102. The first encapsulation 220 may for example be a mold material, a laminate material, a polyimide/epoxy material, or a combination thereof.

The total thickness of the first encapsulation 220 and the first bare die 102 is approximately equal to the thickness of the second bare die 106.

That a total thickness of the first encapsulation 220 and the first bare die 102 is “approximately equal” to the thickness of the second bare die 106 may for example be the case when a difference in thicknesses (between the total thickness of the first encapsulation 220 and the first bare die 102 on the one hand and the second bare die 106 on the other hand) is smaller than 20% (e.g., smaller than 10% or smaller than 5%) of the thickness of the second bare die 106.

An outer surface of the first encapsulation material 220 and an outer surface of the second bare die 106 may be arranged coplanarly. This is to be understood that the encapsulated first bare die 102 and the second bare die 106 are arranged, each of the bare dies 102, 106 with one of their main surfaces, on a common plane, wherein the encapsulated first bare die 102 is arranged with the encapsulated side on the common plane.

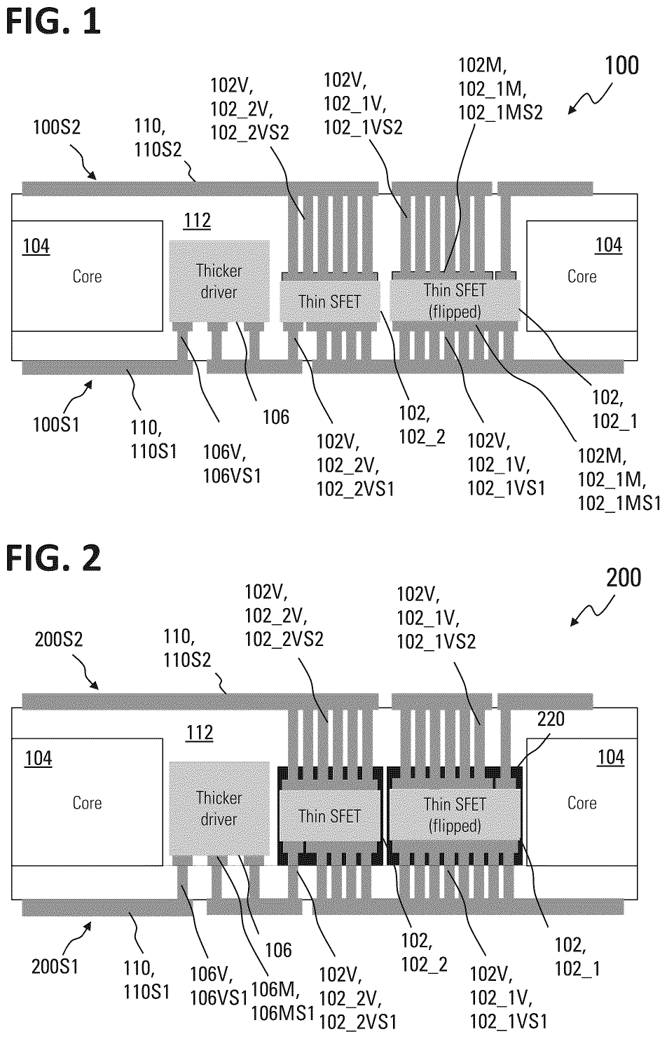

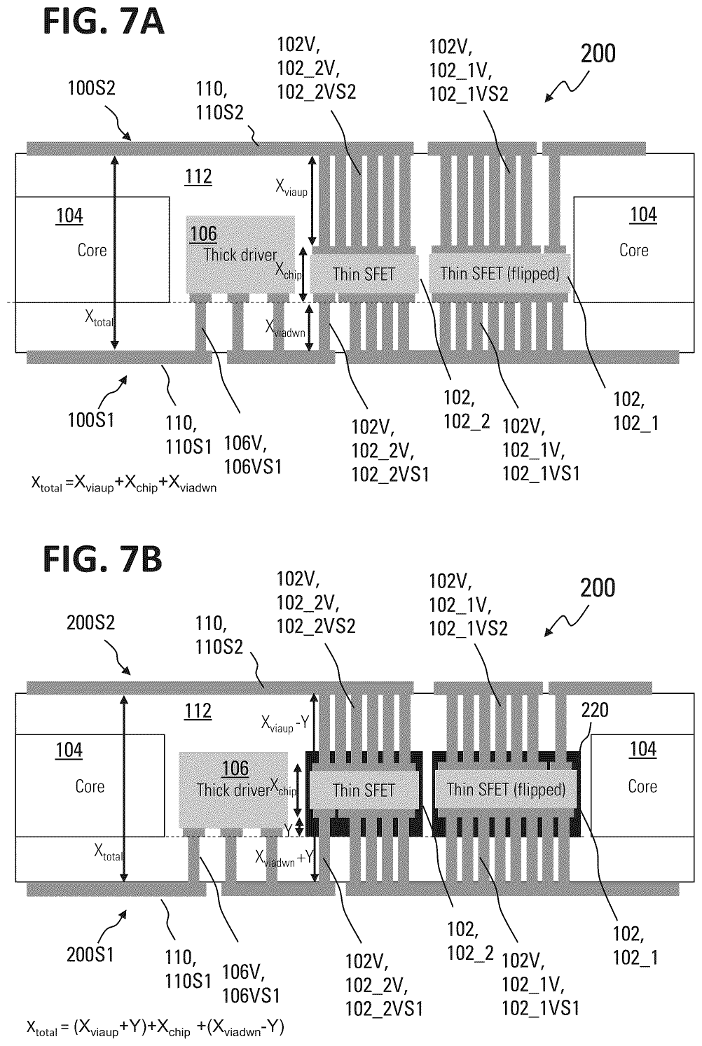

FIGS. 7A and 7B are essentially identical to FIGS. 1 and 2, respectively, but are provided with additional indications, references and formulas for explaining certain effects that may be exploited by using the encapsulated first bare die 102.

In FIGS. 2, 7A, and 7B, the common plane is indicated by a line joining two portions of a core 104 that is part of the die embedded package 200. The second bare die 106 is arranged with its die contacts 106V on the common plane. The encapsulated first bare die 102 is arranged with the encapsulation 220 on the common plane. Thereby, the first bare die 102 is elevated away from the common plane by an amount Y corresponding to a thickness by which the encapsulation 220 extends above die contacts 102V of the first bare die 102. Thereby, a central plane of the first bare die 102 is shifted closer to a central plane of the second bare die 106 than would be the case if the first bare die 102 was arranged with its die contacts 102M on the common plane (this latter case is shown for example in FIGS. 1 and 7A).

The die embedded package 200 may further include a second encapsulation material 112 (also referred to as second encapsulation 112) encapsulating the encapsulated first bare die 102 and the second bare die 106. The second encapsulation 112 may for example be a mold material, a laminate material, a polyimide/epoxy material, or a combination thereof. The first encapsulation 220 and the second encapsulation 112 may be or include the same material or different materials. The second encapsulation 112 may not be arranged at the same time as the first encapsulation 220, but after the first encapsulation 220.

The die embedded package 200 may further include a first set of electrically conductive vias 102_1VS1 electrically contacting the first bare die from a first side of the first bare die 102 and a second set of electrically conductive vias 102_1VS2 electrically contacting the first bare die 102 from a second side of the first bare die 102, wherein the second side is opposite to the first side.

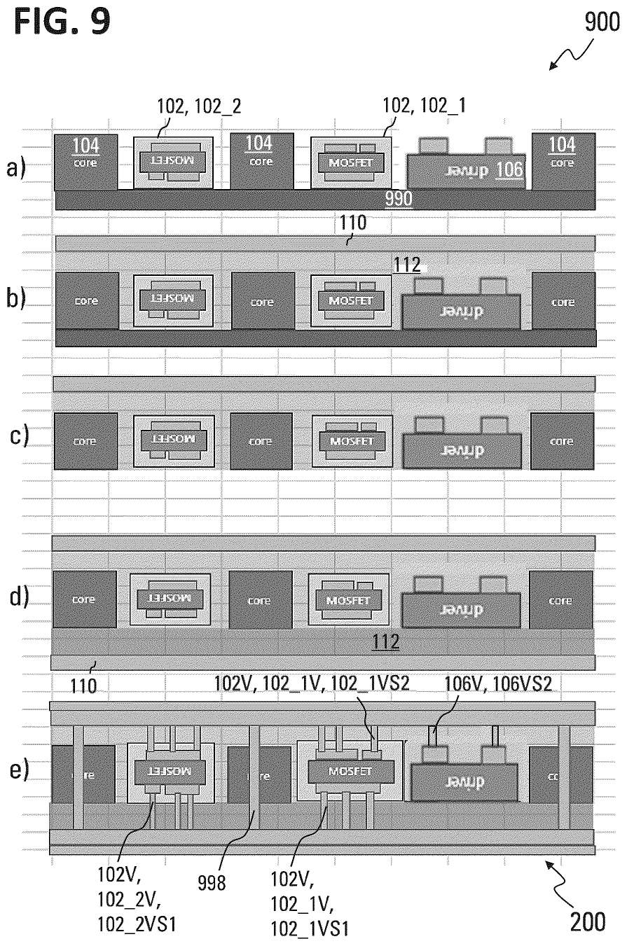

The die embedded package 200 may further include a third set of electrically conductive vias 106V electrically contacting the second bare die 106 from a first side of the second bare die 106 (then also referred to as vias 106VS1, see for example FIG. 2 or FIG. 7A) or from a second side of the second bare die 106 (then also referred to as vias 106VS2, see for example FIG. 9).

In double-sided chip embedding (CE2), a thickness of a die embedded package 100 may typically be determined by the thickest element, e.g. embedded dies 106, and/or possibly a core. The thickest embedded die 106 (and/or the core 104) may usually be arranged more or less centrally between a top- and a bottom surface of the die embedded package 100.

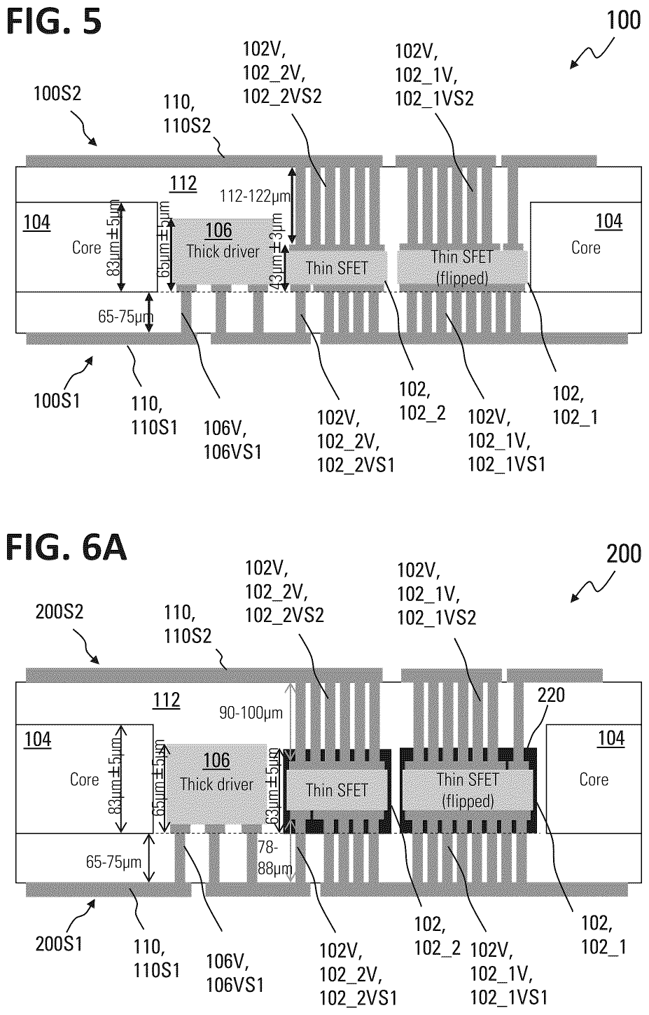

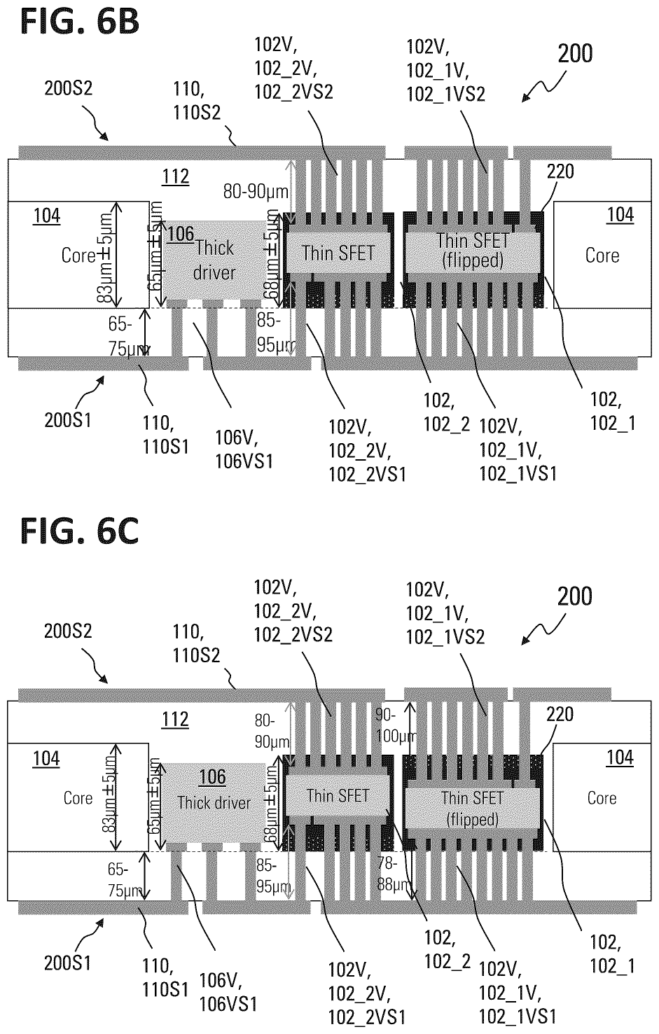

According to a prior art, one outer surface of a thinner die 102 may, due to the processes involved, be arranged coplanar with one of those centrally arranged thicker elements 104, 106—which means that the thinner die 102 is not arranged essentially centered vertically, but offset to the side where it is coplanar with the thicker element 104, 106. This effect is illustrated for example in FIGS. 1, 3, 5, and 7A. Subsequently contacting the thinner die 102 by vias 102_1V1 from the first side and microvias 102_1VS2 from the second side then leads to a situation in which the microvias on the first side 102_1V1 (where the element and the thinner chip are coplanar) are considerably shorter (by the amount Y, see FIG. 7A) than the vias on the second side 102_2V1. Such a length difference in the microvias 102V makes design rules, laser drilling and plating processes (via filling) more complicated.

Furthermore, an unsymmetric via length may lead to a package warpage.

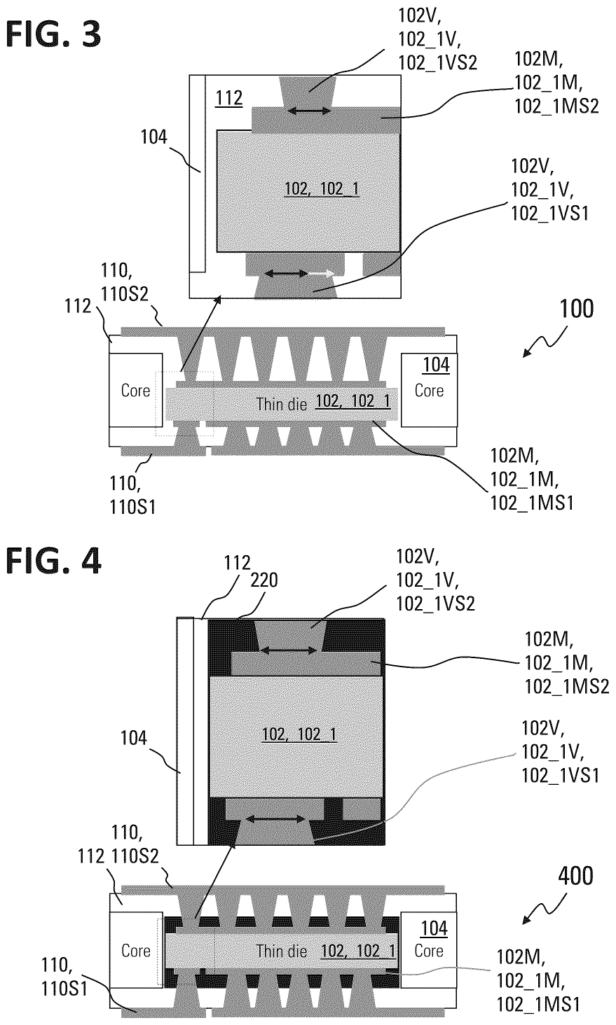

Furthermore, as illustrated in FIG. 3, a significant difference in length between the vias from the first side 102_1VS1 and the microvias from the second side 102_1VS2 may, due to a characteristic cone-shape of the microvias, may cause differences in a size of an area where the microvias 102_1VS1 and 102_1VS2, respectively, interface with die contacts 102_1MS1 and 102_1MS2, respectively. In other words, the shorter microvias have the larger interface area (illustrated by the additional arrow in FIG. 3, at microvia 102_1VS1), which is also undesired.

By effectively decoupling a thickness of the (semiconductor portion) of the die 102 from its arrangement within the die embedded package 200, it is possible to achieve microvias 102_1VS1, 102_1VS2 that are equal or essentially equal in length and thus avoid the above problems. This is illustrated in FIGS. 2, 4, 6A, 6B, 6C, and 7B. In other words, at least some of the vias 102_1VS1 of the first set of electrically conductive vias and at least some of the vias 102_1VS2 of the second set of electrically conductive vias may have the same via length.

In various embodiments, the die embedded package 200 may include a core 104. The core 104 may include or consist of electrically insulating or electrically conductive material, or a combination thereof, for example as commonly used in the art. The core 104 may include at least one opening, which may extend fully or partially through the core 104.

In the at least one opening, the first bare die 102 and the second bare die 106 are arranged. The first bare die 102 and the second bare die 106 may be arranged in a common opening (as shown in FIGS. 2, 4, 6A to 6C, and 7B. Alternatively, the first bare die 102 and the second bare die 106 may be arranged in separate openings.

In various embodiments, the die embedded package 200 may optionally further include at least one further first bare die 102_2, and (per further first bare die 102_2) a further first set of electrically conductive vias 102_2VS1 electrically contacting the further first bare die 102_2 from a first side of the first bare die 102_2, and a further second set of electrically conductive vias 102_2VS2 electrically contacting the further first bare die 102_2 from a second side of the further first bare die 102_2, the second side opposite to the first side.

A relative arrangement of the dies 102_1, 102_2, 106 with respect to each other may depend on the desired application. For example, all dies 102_1, 102_2, 106 may be in separate openings of the core 104, all dies 102_1, 102_2, 106 may be in the same opening (see for example FIGS. 2, 6A to 6C, and 7B), two of the dies (e.g., 102_1, 106) may be in a common opening, and one or more of the other dies (e.g., 106) may be in a different, opening (see for example FIG. 9), etc.

In various embodiments, the first bare die 102_1 and the further first bare die 102_2 may be arranged together in the first encapsulation 220.

In various embodiments, the further first bare die 102_2 may be arranged in a further first encapsulation 220 that is separate from the first encapsulation 220.

In various embodiments, more than two first dies 102_1 may be arranged together in the first encapsulation 220.

Absolute and relative orientations of the first bare die 102, the second bare die 106, and optional further dies (e.g., the further first bare die 102_2) may be chosen as desired. For example, FIGS. 2, 4, 6A to 6C, and 7B show a flipped configuration of two (otherwise optionally similar or identical) first bare dies 102_1, 102_2. The first bare dies 102_1, 102_2 in those exemplary embodiments may for example be transistors, e.g. power transistors, e.g. SFETs. One of the first bare dies (e.g., 102_1) may be oriented with its drain contact towards the first side of the die embedded package 200, and the further first bare die 102_2 may be arranged with its source and gate contacts towards the first side of the die embedded package 200. Other embodiments may require both first bare dies 102 to have the same orientation, etc.

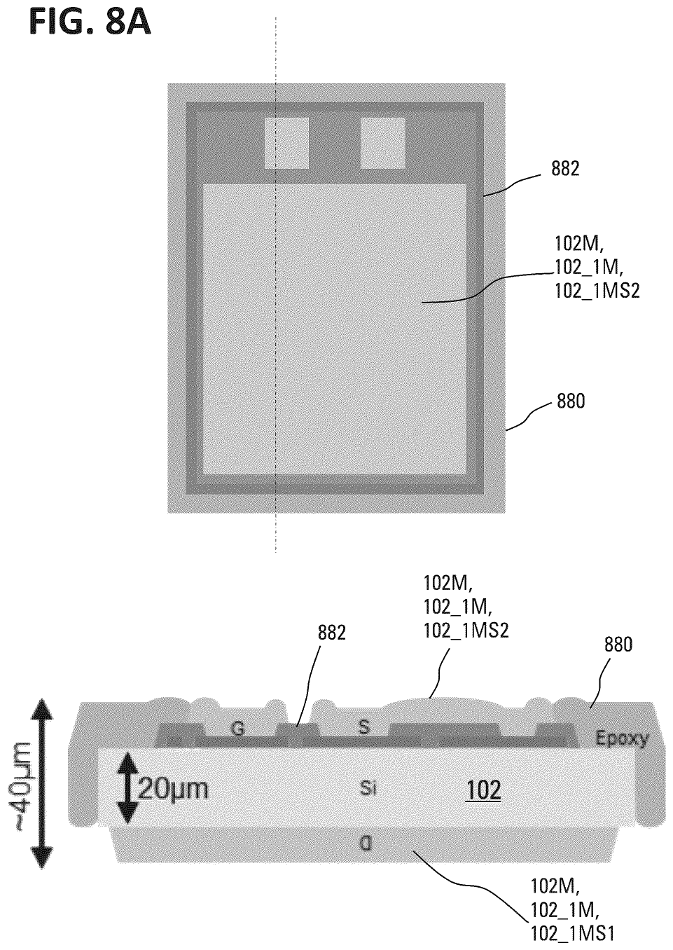

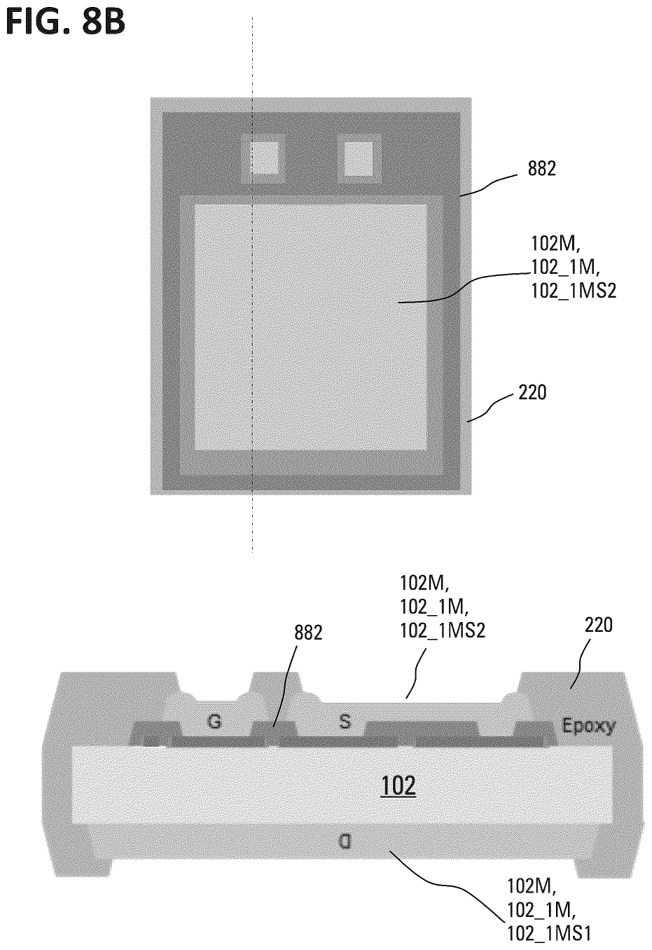

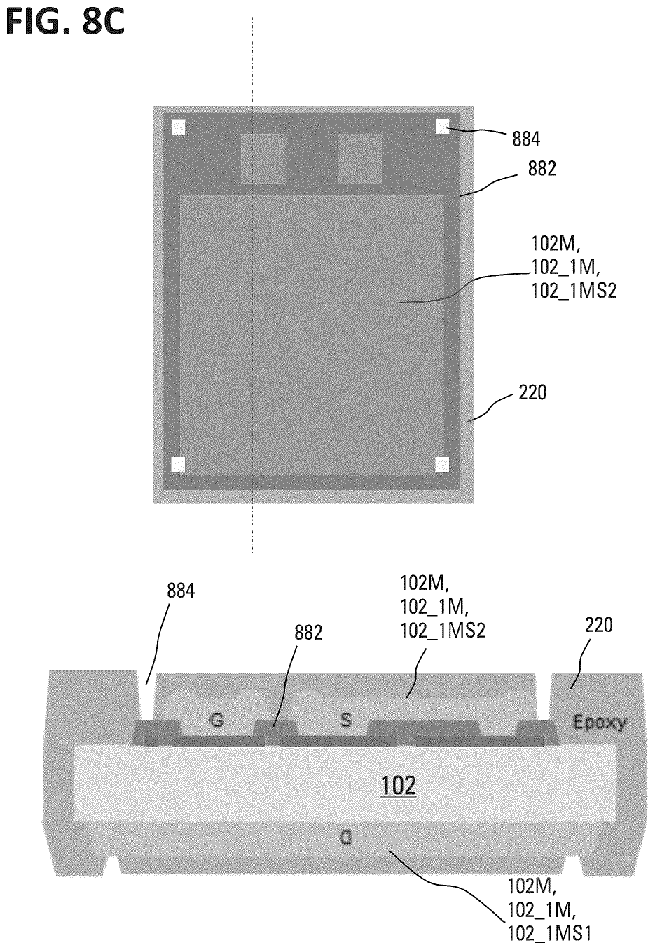

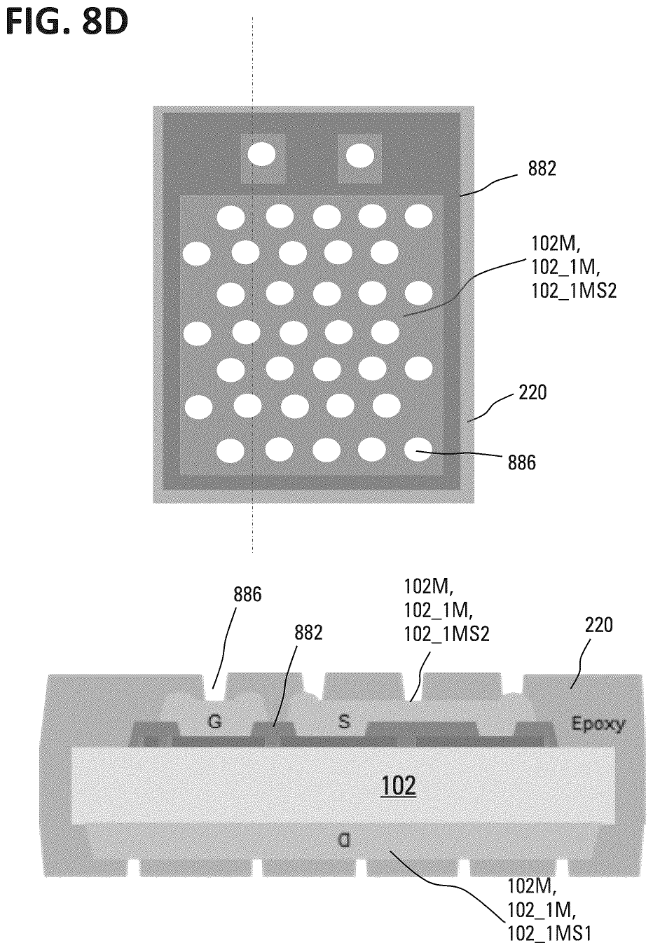

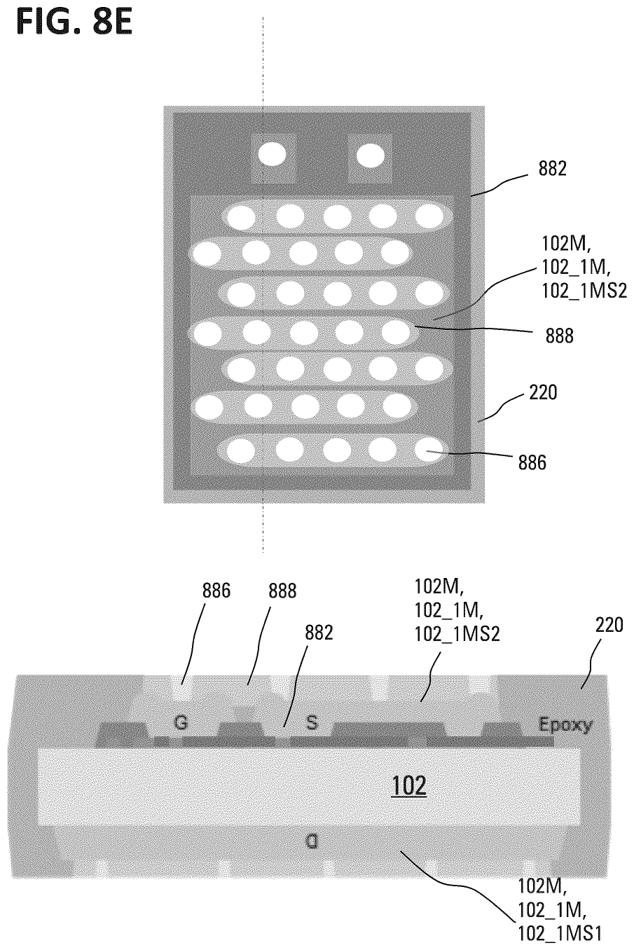

Each of FIGS. 8B to 8E shows a schematic top view and a schematic cross-sectional view of a first die 102 with first encapsulation material 220 as used in a die embedded package 200 in accordance with various embodiments.

In various embodiments, the first encapsulation material 220 may be arranged on all sides of the first bare die 102. The first encapsulation material 220 may completely cover the first bare die 102 on all sides (shown in FIG. 9); may include alignment openings as shown in FIGS. 8C, which may extend partially or fully through the encapsulation material (as an alternative to openings as alignment indicators, markings, e.g. on an outside of the die embedded package 200, may be used; the alignment indicators may be used for aligning the first bare die during subsequent processing); may partially (see FIGS. 8D and 8E, where the first encapsulation material 220 is removed only in via locations or in via row locations) or almost fully (see FIG. 8B) expose die contacts 102M on the first side and/or on the second side of the first bare die 102; or may be arranged only on one of the main sides of the first bare die 102, and optionally on side surfaces connecting the first side of the first bare die 102 with the second side of the first bare die 102.

To provide the first encapsulation only on either the first side or the second side may be sufficient for adjusting the vertical position of the first bare die 102 within the die embedded package 200, provided that the first encapsulation 220 is arranged to extend further away from a central plane of the first bare die 102 than a surface of the die contact 102_1M on same side of the first bare die 102 (or the semiconductor material of the first bare die 102). Such an embodiment is shown in the example of FIG. 10B, and also in FIG. 11, which includes two bare dies 102 within the same first encapsulation 220.

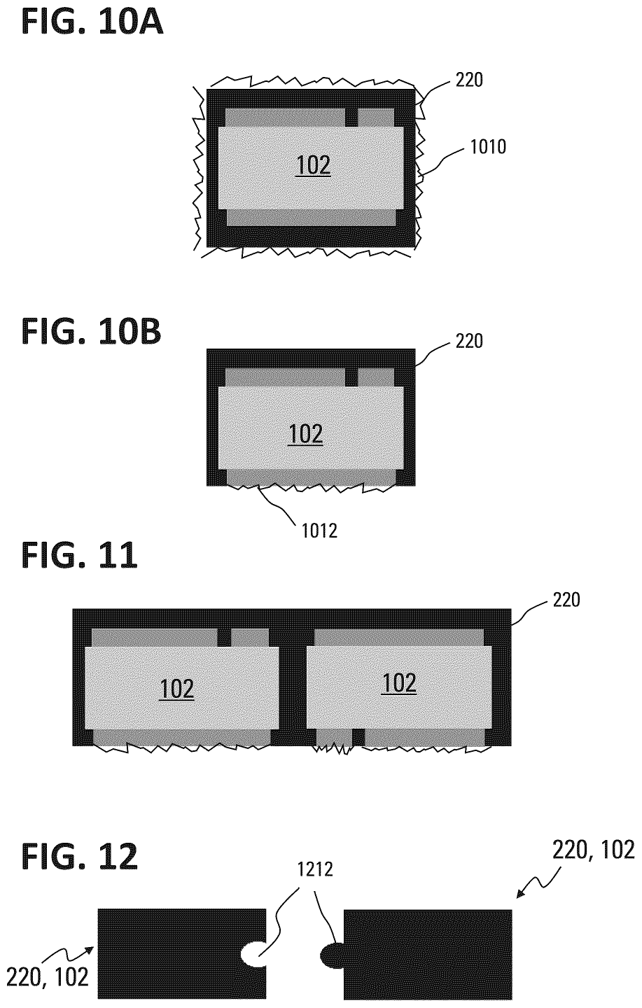

FIG. 12 illustrates only the first encapsulation 220 of the die embedded package 200, which may be structured with an interlock feature 1212, like for example jigsaw puzzle structures including a protrusion on one of the die embedded packages 200, and a matching notch on the other of the die embedded packages 200. This may enable a defined combination of separate die embedded packages 200.

From a die protection point of view, a more or less full coverage of the first die 102 may be preferred. Depending on a level of protection that is provided by the first encapsulation 220, PCB processes may be done without handling a bare die. This means that the core competences of a semiconductor company and a PCB manufacturer mainly remain the same, such that the strength of both can be used for the final product. This leads to a higher yield because handling/contamination/ESD issues of a bare die may be avoided by protecting it in advance.

Additionally reliability topics due to wrong handling of bare dies on PCB side may possibly be reduced, too.

A further aspect is that the adhesion of the protection layer to the die can be realized by commonly used processes (like A2, Silane, Cu roughening) and is no longer a not fully solved problem for the CE2 process.

In various embodiments (FIG. 10A illustrates an example), the first encapsulation material 220 may be provided with an adhesion promoter 1010 on its outer surface. Even though the adhesion promoter 1010 is depicted as an additional layer, any type of adhesion promotion known in the art may be employed, for example applying of a material layer like silane, chemical processing (e.g., plasma processing) of the surface of the first encapsulation material 220, mechanical processing of the first encapsulation material 220 (e.g. roughening), etc. The adhesion promoter 1010 may be configured to improve an adhesion between the first encapsulation material 220 and the second encapsulation material 112. Even though FIG. 10A illustrates a treatment of all outer surfaces, treating only a portion of the outer surface of the first encapsulation material 220 may already be beneficial, and possibly sufficient.

In various embodiments, exposed metal surfaces of the first bare die 102 (and/or of the second bare die 106, and optionally of further dies, may be treated with an adhesion promoter, for example as known in the art, e.g. by processes similar to those described for the first encapsulation material 220 and adjusted to the metal material. For example, Cu roughening may be used.

FIG. 9 illustrates, as a sequence of individual panels, a method of forming a die embedded package 200 in accordance with various embodiments, for example as described above.

The method may include encapsulating a first bare die with a first encapsulation material 220, the first bare die 102 being thinner than a second bare die 106, wherein the total thickness of the first encapsulation 220 and the first bare die 102 is approximately equal to the thickness of the second bare die 106 (this is not shown as a separate process in FIG. 9—the first bare die 102 is already encapsulated by the first encapsulation material 220 in panel a).

The method may further include arranging the encapsulated first bare die 102 and the second bare die 106. The dies 102, 106 may for example be arranged on a temporary carrier 990, for example in openings of a core 104, with an outer surface of the first encapsulation material 220 and an outer surface of the second bare die 106 arranged coplanarly (see panel a)).

The method may further include encapsulating the encapsulated first bare die 102 and the second bare die 106 with a second encapsulation material 112. This may for example be achieved by laminating the dies 102, 106 (and the core 104) from the second side with a laminating material 112, optionally with a metal layer, e.g. a top redistribution layer, 110 at the same time, e.g. as a prepreg material with a copper layer (see panel b)), subsequently removing the temporary carrier 990 (see panel c), and arranging a bottom portion of the second encapsulation material 112, e.g. further laminating material 112, optionally with a second metal layer, e.g., a bottom redistribution layer 110, at the same time (see panel d).

The method may further include electrically contacting the first bare die 102 from a first side of the first bare die 102 by forming a first set of electrically conductive vias 102_1VS1, electrically contacting the first bare die 102 from a second side of the first bare die 102 by forming a second set of electrically conductive vias 102_1VS2, the second side opposite to the first side, and electrically contacting the second bare die 106 from a first side of the second bare die 106 or (as shown in panel e)) from a second side of the second bare die 106 by forming a third set of electrically conductive vias 106VS2.

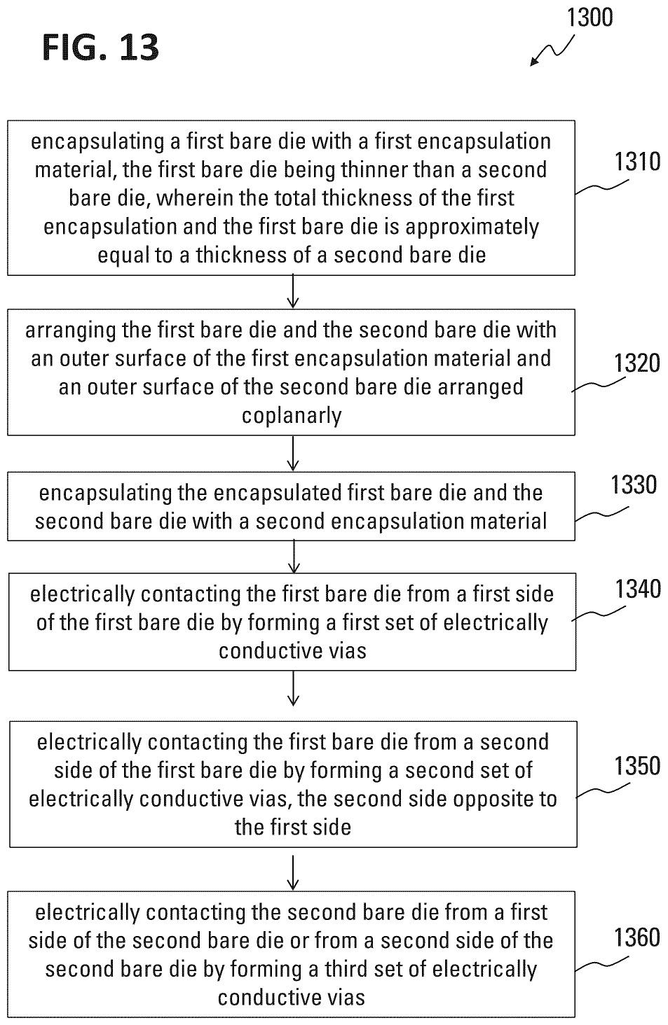

FIG. 13 shows a flow diagram 1300 of a method of forming a die embedded package in accordance with various embodiments.

The method may include encapsulating a first bare die with a first encapsulation material, the first bare die being thinner than a second bare die, wherein the total thickness of the first encapsulation and the first bare die is approximately equal to a thickness of the second bare die (1310), arranging the first bare die and the second bare die with an outer surface of the first encapsulation material and an outer surface of the second bare die arranged coplanarly (1320), encapsulating the encapsulated first bare die and the second bare die with a second encapsulation material (1330), electrically contacting the first bare die from a first side of the first bare die by forming a first set of electrically conductive vias (1340), electrically contacting the first bare die from a second side of the first bare die by forming a second set of electrically conductive vias, the second side opposite to the first side (1350), and electrically contacting the second bare die from a first side of the second bare die or from a second side of the second bare die by forming a third set of electrically conductive vias (1360).

FIG. 4 shows a schematic cross-sectional view of a die embedded package 400 in accordance with various embodiments.

In the above description, the second bare die 106 was mostly responsible for not being able to choose a thickness of the die embedded package 200 suitable for the (small) thickness of the first bare die 102.

However, other constraints may lead to a similar situation with a die embedded package 400 that may include only a single first bare die 102, or optionally a plurality of single first bare dies 102. For example, the core 104 may define a thickness of the die embedded package 400 and may be (e.g., significantly) thicker than the first bare die 102.

In such a scenario, a similar strategy may be employed as described above for the embodiments that include both the first bare die 102 and the second bare die 106.

In various embodiments, as for example illustrated in FIG. 4, a die embedded package 400 may include a bare die 102, a first encapsulation material 220 encapsulating the first bare die 102, a second encapsulation material 112 encapsulating the encapsulated first bare die 102, a first set of electrically conductive vias 102_1V1 electrically contacting the first bare die 102 from a first side of the first bare die 102 and a second set of electrically conductive vias 102_1V2 electrically contacting the first bare die 102 from a second side of the first bare die 102, the second side opposite to the first side, wherein at least some of the vias of the first set of electrically conductive vias 102_1V1 and at least some of the vias of the second set of electrically conductive vias 102_1V2 have the same via length.

Regarding other properties of the die embedded package 400, the above descriptions related to the die embedded package 200 may apply mutatis mutandis, for example regarding used materials and processes, thicknesses, advantages of having approximately symmetric via lengths, etc.

Various examples will be illustrated in the following:

Example 1 is a die embedded package. The die embedded package may include a first bare die and a second bare die, the first bare die being thinner than the second bare die, a first encapsulation material encapsulating the first bare die, wherein the total thickness of the first encapsulation and the first bare die is approximately equal to the thickness of the second bare die and wherein an outer surface of the first encapsulation material and an outer surface of the second bare die are arranged coplanarly, a second encapsulation material encapsulating the encapsulated first bare die and the second bare die. a first set of electrically conductive vias electrically contacting the first bare die from a first side of the first bare die and a second set of electrically conductive vias electrically contacting the first bare die from a second side of the first bare die, the second side opposite to the first side, and a third set of electrically conductive vias electrically contacting the second bare die from a first side of the second bare die or from a second side of the second bare die.

In Example 2, the subject-matter of Example 1 may optionally include that at least some of the vias of the first set of electrically conductive vias and at least some of the vias of the second set of electrically conductive vias have the same via length.

In Example 3, the subject-matter of Example 1 or 2 may optionally include that a thickness of the first bare die is between about 30 μm and 50 μm.

In Example 4, the subject-matter of any of Examples 1 to 3 may optionally include that the first bare die is a double-sided die having die contacts on its first side and on its second side.

In Example 5, the subject-matter of Example 4 may optionally include that the die contacts on the first side of the first bare die are connected to the first set of vias, and the die contacts on the second side of the first bare die are connected to the second set of vias.

In Example 6, the subject-matter of any of Examples 1 to 5 may optionally include that the second bare die is a single-sided die having die contacts only on its first side.

In Example 7, the subject-matter of Example 6 may optionally include that the die contacts on the first side of the second bare die are connected to the third set of vias.

In Example 8, the subject-matter of Example 4 or 5 may optionally include that a surface area of each via of the first set of vias at the die contacts on the first side of the first bare die is approximately the same as a surface area of each via of the second set of vias at the die contacts on the second side of the first bare die.

In Example 9, the subject-matter of any of Examples 1 to 8 may optionally further include a core including an opening, wherein the first bare die and the second bare die are arranged in the opening.

In Example 20, the subject-matter of Example 9 may optionally include that the opening extends fully or partially through the core.

In Example 11, the subject-matter of any of Examples 1 to 10 may optionally include that the first encapsulation material is arranged on all sides of the first bare die.

In Example 12, the subject-matter of any of Examples 1 to 11 may optionally include that the first encapsulation material is arranged to expose die contacts on the first side and/or on the second side of the first bare die.

In Example 13, the subject-matter of any of Examples 1 to 12 may optionally include that the first encapsulation material is arranged to expose die contacts on the first side and/or on the second side of the first bare die only in via locations.

In Example 14, the subject-matter of any of Examples 1 to 11 may optionally include that the first encapsulation material is arranged to fully encapsulate the first bare die, optionally except for alignment marks.

In Example 15, the subject-matter of Example 14 may optionally include that the alignment marks extend partially or fully through the encapsulation material.

In Example 16, the subject-matter of any of Examples 1 to 15 may optionally include that the first bare die and the second bare die are arranged next to each other.

In Example 17, the subject-matter of Example 4 or 5 may optionally include that the first encapsulation is arranged to extend further away from a central plane of the first bare die than a surface of the die contact on same side of the first bare die.

In Example 18, the subject-matter of any of Examples 1 to 17 may optionally include that the first encapsulation material is provided with an adhesion promoter on its outer surface.

In Example 19, the subject-matter of any of Examples 1 to 15 may optionally further include a further first bare die, and a further first set of electrically conductive vias electrically contacting the further first bare die from a first side of the first bare die and a further second set of electrically conductive vias electrically contacting the further first bare die from a second side of the further first bare die, the second side opposite to the first side.

In Example 20, the subject-matter of Example 19 may optionally include that the first bare die and the further first bare die are arranged together in the first encapsulation.

In Example 21, the subject-matter of Example 19 may optionally include that the further first bare die is arranged in a further first encapsulation that is separate from the first encapsulation.

In Example 22, the subject-matter of any of Examples 1 to 21 may optionally include that the first bare die is a power semiconductor die.

In Example 23, the subject-matter of any of Examples 1 to 22 may optionally include that the second bare die is a control die.

Example 24 is a die embedded package. The die embedded package may include a bare die, a first encapsulation material encapsulating the first bare die, a second encapsulation material encapsulating the encapsulated first bare die, a first set of electrically conductive vias electrically contacting the first bare die from a first side of the first bare die and a second set of electrically conductive vias electrically contacting the first bare die from a second side of the first bare die, the second side opposite to the first side, wherein at least some of the vias of the first set of electrically conductive vias and at least some of the vias of the second set of electrically conductive vias have the same via length.

In Example 25, the subject-matter of Example 24 may optionally further include a core including an opening, wherein the bare die is arranged in the opening.

Example 26 is a method of forming a die embedded package. The method may include encapsulating a first bare die with a first encapsulation material, the first bare die being thinner than a second bare die, wherein the total thickness of the first encapsulation and the first bare die is approximately equal to a thickness of the second bare die, arranging the first bare die and the second bare die with an outer surface of the first encapsulation material and an outer surface of the second bare die arranged coplanarly, encapsulating the encapsulated first bare die and the second bare die with a second encapsulation material, electrically contacting the first bare die from a first side of the first bare die by forming a first set of electrically conductive vias, electrically contacting the first bare die from a second side of the first bare die by forming a second set of electrically conductive vias, the second side opposite to the first side, and electrically contacting the second bare die from a first side of the second bare die or from a second side of the second bare die by forming a third set of electrically conductive vias.

In Example 27, the subject-matter of Example 26 may optionally include that at least some of the vias of the first set of electrically conductive vias and at least some of the vias of the third set of electrically conductive vias have the same via length.

In Example 28, the subject-matter of Example 26 or 27 may optionally include that a thickness of the first bare die is between about 30 μm and 50 μm.

In Example 29, the subject-matter of any of Examples 26 to 28 may optionally include that the first bare die is a double-sided die having die contacts on its first side and on its second side.

In Example 30, the subject-matter of Example 29 may optionally include that the die contacts on the first side of the first bare die are connected to the first set of vias, and the die contacts on the second side of the first bare die are connected to the second set of vias.

In Example 31, the subject-matter of any of Examples 26 to 30 may optionally include that the second bare die is a single-sided die having die contacts only on its first side.

In Example 32, the subject-matter of Example 31 may optionally include that the die contacts on the first side of the first bare die are connected to the third set of vias.

In Example 33, the subject-matter of Example 29 or 30 may optionally include that a surface area of each via of the first set of vias at the die contacts on the first side of the first bare die is approximately the same as a surface area of each via of the second set of vias at the die contacts on the second side of the first bare die.

In Example 34, the subject-matter of any of Examples 26 to 33 may optionally further include a core including an opening, wherein the first bare die and the second bare die are arranged in the opening.

In Example 35, the subject-matter of Example 34 may optionally include that the opening extends fully or partially through the core.

In Example 36, the subject-matter of any of Examples 26 to 35 may optionally further include the encapsulating the first bare die with a first encapsulation material includes arranging the encapsulation material on all sides of the first bare die.

In Example 37, the subject-matter of any of Examples 26 to 33 may optionally further include the encapsulating the first bare die with a first encapsulation material includes arranging the first encapsulation material to expose die contacts on the first side and/or on the second side of the first bare die.

In Example 38, the subject-matter of any of Examples 26 to 37 may optionally further include the encapsulating the first bare die with a first encapsulation material includes arranging the first encapsulation material to expose die contacts on the first side and/or on the second side of the first bare die only in via locations.

In Example 39, the subject-matter of any of Examples 26 to 33 may optionally further include the encapsulating the first bare die with a first encapsulation material includes arranging the first encapsulation material to fully encapsulate the first bare die, optionally except for alignment marks.

In Example 40, the subject-matter of Example 39 may optionally include that the alignment marks extend partially or fully through the encapsulation material.

In Example 41, the subject-matter of any of Examples 26 to 40 may optionally further include the first bare die and the second bare die are arranged next to each other.

In Example 42, the subject-matter of any of Examples 26 to 41 may optionally further include the first encapsulation is arranged to extend further away from a central plane of the first bare die than a surface of the die contact on same side of the first bare die.

In Example 43, the subject-matter of any of Examples 26 to 42 may optionally further include providing the first encapsulation material with an adhesion promoter on its outer surface.

In Example 44, the subject-matter of any of Examples 26 to 43 may optionally further include arranging a further first bare die, and
electrically contacting the further first bare die from a first side of the further first bare die by a further first set of electrically conductive vias, and
electrically contacting the further first bare die from a second side of the further first bare die by a further second set of electrically conductive vias electrically contacting the further first bare die from a second side of the further first bare die, the second side opposite to the first side.

In Example 45, the subject-matter of Example 44 may optionally include that the first bare die and the further first bare die are arranged together in the first encapsulation.

In Example 46, the subject-matter of Example 44 may optionally include that the further first bare die is arranged in a further first encapsulation that is separate from the first encapsulation.

In Example 47, the subject-matter of any of Examples 26 to 42 may optionally further include the first bare die is a power semiconductor die.

In Example 48, the subject-matter of any of Examples 26 to 33 may optionally further include the second bare die is a control die.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A die embedded package, comprising:
a first bare die and a second bare die, the first bare die being thinner than the second bare die;
a first encapsulation material encapsulating the first bare die, wherein the total thickness of the first encapsulation and the first bare die is approximately equal to the thickness of the second bare die and wherein an outer surface of the first encapsulation material and an outer surface of the second bare die are arranged coplanarly;
a second encapsulation material encapsulating the encapsulated first bare die and the second bare die,
a first set of electrically conductive vias electrically contacting the first bare die from a first side of the first bare die and a second set of electrically conductive vias electrically contacting the first bare die from a second side of the first bare die, the second side opposite to the first side; and
a third set of electrically conductive vias electrically contacting the second bare die from a first side of the second bare die or from a second side of the second bare die.

2. The die embedded package of claim 1, wherein at least some of the vias of the first set of electrically conductive vias and at least some of the vias of the second set of electrically conductive vias have the same via length.

3. The die embedded package of claim 1, wherein the first bare die is a double-sided die having die contacts on its first side and on its second side.

4. The die embedded package of claim 3, wherein the die contacts on the first side of the first bare die are connected to the first set of vias, and the die contacts on the second side of the first bare die are connected to the second set of vias.

5. The die embedded package of claim 1, further comprising:
a core comprising an opening,
wherein the first bare die and the second bare die are arranged in the opening.

6. The die embedded package of claim 1, wherein the first encapsulation material is arranged to expose die contacts on the first side and/or on the second side of the first bare die only in via locations.

7. The die embedded package of claim 1, wherein the first encapsulation material is arranged to fully encapsulate the first bare die, optionally except for alignment marks.

8. The die embedded package of claim 7, wherein the alignment marks extend partially or fully through the encapsulation material.

9. The die embedded package of claim 1, wherein the first encapsulation material is provided with an adhesion promoter on its outer surface.

10. The die embedded package of claim 1, further comprising:
a further first bare die; and
a further first set of electrically conductive vias electrically contacting the further first bare die from a first side of the first bare die and a further second set of electrically conductive vias electrically contacting the further first bare die from a second side of the further first bare die, the second side opposite to the first side.

11. A die embedded package, comprising:
a bare die;
a first encapsulation material encapsulating the first bare die;
a second encapsulation material encapsulating the encapsulated first bare die;
a first set of electrically conductive vias electrically contacting the first bare die from a first side of the first bare die and a second set of electrically conductive vias electrically contacting the first bare die from a second side of the first bare die, the second side opposite to the first side, wherein at least some of the vias of the first set of electrically conductive vias and at least some of the vias of the second set of electrically conductive vias have the same via length.

12. The die embedded package of claim 11, further comprising:
a core comprising an opening,
wherein the bare die is arranged in the opening.

13. A method of forming a die embedded package, the method comprising:
encapsulating a first bare die with a first encapsulation material, the first bare die being thinner than a second bare die, wherein the total thickness of the first encapsulation and the first bare die is approximately equal to a thickness of the second bare die;
arranging the first bare die and the second bare die with an outer surface of the first encapsulation material and an outer surface of the second bare die arranged coplanarly;
encapsulating the encapsulated first bare die and the second bare die with a second encapsulation material;
electrically contacting the first bare die from a first side of the first bare die by forming a first set of electrically conductive vias;
electrically contacting the first bare die from a second side of the first bare die by forming a second set of electrically conductive vias, the second side opposite to the first side; and
electrically contacting the second bare die from a first side of the second bare die or from a second side of the second bare die by forming a third set of electrically conductive vias.

14. The method of claim 13, wherein at least some of the vias of the first set of electrically conductive vias and at least some of the vias of the third set of electrically conductive vias have the same via length.

15. The method of claim 13, wherein the die contacts on the first side of the first bare die are connected to the first set of vias, and the die contacts on the second side of the first bare die are connected to the second set of vias.

16. The method of claim 13, wherein the encapsulating the first bare die with a first encapsulation material comprises arranging the first encapsulation material to expose die contacts on the first side and/or on the second side of the first bare die only in via locations.

17. The method of claim 13, wherein the encapsulating the first bare die with a first encapsulation material comprises arranging the first encapsulation material to fully encapsulate the first bare die, optionally except for alignment marks.

18. The method of claim 17, wherein the alignment marks extend partially or fully through the encapsulation material.

19. The method of claim 13, further comprising:
providing the first encapsulation material with an adhesion promoter on its outer surface.

20. The method of claim 13, further comprising:
arranging a further first bare die; and
electrically contacting the further first bare die from a first side of the further first bare die by a further first set of electrically conductive vias; and
electrically contacting the further first bare die from a second side of the further first bare die by a further second set of electrically conductive vias electrically contacting the further first bare die from a second side of the further first bare die, the second side opposite to the first side.
